(19) United States
(12) Patent Application Publication
(10) Pub. No.: US 2017/0233867 A1
(43) Pub. Date: Aug. 17, 2017

(54) VAPOR PHASE GROWTH APPARATUS AND VAPOR PHASE GROWTH METHOD

(71) Applicant: NuFlare Technology, Inc., Kanagawa (JP)

(72) Inventors: Hideshi TAKAHASHI, Yokohama-shi (JP); Yuusuke SATO, Tokyo (JP)

(21) Appl. No.: 15/585,944

(22) Filed: May 3, 2017

Related U.S. Application Data
(63) Continuation of application No. PCT/JP2015/081003, filed on Nov. 4, 2015.

(30) Foreign Application Priority Data
Nov. 7, 2014 (JP) 2014-227546

(51) Int. Cl. C23C 16/455; C23C 16/52; C23C 16/18

(52) U.S. Cl. CPC C23C 16/45561; C23C 16/18; C23C 16/52; C23C 16/45557

(57) ABSTRACT

A vapor phase growth apparatus according to as embodiment includes n reaction chambers, a main gas supply path supplying a process gas to the n reaction chambers, a main mass flow controller controlling a flow rate of the process gas, a branch portion branching the main gas supply path, n sub gas supply paths branched from the main gas supply path at the branch portion, the n sub gas supply paths supplying branched process gases to the n reaction chambers, n first stop valves in the n sub gas supply paths between the branch portion and the n reaction chambers, distances from the n first stop valves to the branch portion are less than distances from the n first stop valves to the n reaction chambers, and n sub mass flow controllers in the n sub gas supply paths between the n first stop valves and the n reaction chambers.

### CROSS-REFERENCE TO RELATED APPLICATION

This application is continuation application of, and claims the benefit of priority from the International Application PCT/JP2015/081003, filed Nov. 4, 2015, which claims the benefit of priority from Japanese Patent Application No. 2014-227546, filed on Nov. 7, 2014, the entire contents of all of which are incorporated herein by reference.

### FIELD OF THE INVENTION

Embodiments described herein relate generally to a vapor phase growth apparatus and a vapor phase growth method.

### BACKGROUND OF THE INVENTION

As a method for forming a high-quality semiconductor film, there is an epitaxial growth technique which grows a single-crystal film on a substrate, such as a wafer, using vapor phase growth. In a vapor phase growth apparatus using the epitaxial growth technique, a wafer is placed on a support portion in a reaction chamber which is maintained at normal pressure or reduced pressure. Then, process gas, such as source gas which will be a raw material for forming a film, is supplied from, for example, a shower plate provided in an upper part of the reaction chamber to the surface of the wafer while the wafer is being heated. For example, the thermal reaction of the source gas occurs in the surface of the wafer and an epitaxial single-crystal film is formed on the surface of the wafer.

In recent years, as a material forming a light emitting device or a power device, a gallium nitride (GaN)-based semiconductor device has drawn attention. There is a metal organic chemical vapor deposition method (MOCVD method) as an epitaxial growth technique that forms a GaN-based semiconductor film. In the metal organic chemical vapor deposition method, organic metal, such as trimethylgallium (TMG) trimethylindium (TMI), trimethylaluminum (TMA), or ammonia (NH₃) is used as the source gas.

In some cases, a vapor phase growth apparatus including a plurality of reaction chambers is used in order to improve productivity. Japanese Patent Publication No. 2003-49278 discloses a method that forms a film using a vapor phase growth apparatus including a plurality of reaction chambers and stops processing when an abnormality occurs in one reaction chamber.

### SUMMARY OF THE INVENTION

A vapor phase growth apparatus according to an aspect of the invention includes: n is an integer equal to or greater than 2) reaction chambers; a main gas supply path supplying process gas to the n reaction chambers; a main mass flow controller provided in the main gas supply path, the main mass flow controller controlling a flow rate of the process gas through the main gas supply path; a branch portion branching the main gas supply path; n sub gas supply paths branched from the main gas supply path at the branch portion, the n sub gas supply paths supplying branched process gases to the n reaction chambers; n first stop valves provided in the n sub gas supply paths between the branch portion and the n reaction chambers, distances from the n first stop valves to the branch portion are less than distances from the n first stop valves to the n reaction chambers, the n first stop valves being capable of stopping the flow of the process gas to the n reaction chambers; and n sub mass flow controllers provided in the n sub gas supply paths between the n first stop valves and the n reaction chambers, the n sub mass flow controllers controlling a flow rate of the process gas through the n sub gas supply paths.

A vapor phase growth method according to another aspect of the invention includes: loading substrates to each of n (n is an integer equal to or greater than 2) reaction chambers; introducing a process gas controlled to a predetermined flow rate to a main gas supply path; introducing branched process gases ton sub gas supply paths branched from the main gas supply path at a controlled flow rate; supplying the process gas from the n sub gas supply paths to the n reaction chambers to form films on the substrates; and when an abnormality occurs in any one of the n reaction chambers, instantly stopping the introduction of the process gas to the sub gas supply paths connected to the reaction chamber in which the abnormality has occurred, calculating a total flow rate of the process gas supplied to the reaction chambers other than the reaction chamber from which the abnormality has been detected, and controlling the flow rate of the process gas introduced to the main gas supply path.

### BRIEF DESCRIPTION OF THE DRAWINGS

FIG. 1 is a diagram illustrating the structure of a vapor phase growth apparatus according to an embodiment;

FIG. 2 is a diagram illustrating a branch portion and first stop valves according to the embodiment; and

FIG. 3 is a diagram schematically illustrating the branch portion and the first stop valves according to the embodiment.

### DETAILED DESCRIPTION OF THE EMBODIMENTS

Hereinafter, embodiments of the invention will be described with reference to the drawings.

In the specification, the direction of gravity in a state in which a vapor phase growth apparatus is provided so as to form a film is defined as a “lower” direction and a direction opposite to the direction of gravity is defined as an “upper” direction. Therefore, a “lower portion” means a position in the direction of gravity relative to the reference and a “lower side” means the direction of gravity relative to the reference. In addition, an “upper portion” means a position. in the direction opposite to the direction of gravity relative to the reference and an “upper side” means the direction opposite to the direction of gravity relative to the reference. Furthermore, a “longitudinal direction” is the direction of gravity.

In the specification, “process gas” is a general term of gas used to form a film on a substrate. The concept of the “process gas” includes, for example, source gas, carrier gas, and separation gas.

In the specification, “separation gas” is process gas that is introduced into a reaction chamber of the vapor phase growth apparatus and is a general term of gas that is used to separate process gases of a plurality of raw material gases.

A vapor phase growth apparatus according to an embodiment of the invention includes: n (n is an integer equal to or greater than 2) reaction chambers; a main gas supply path supplying a process gas to the n reaction chambers; a main mass flow controller that is provided in the main gas supply path and controls a flow rate of the process gas through the main gas supply path; a branch portion that branches the main gas supply path; n sub gas supply paths that are branched from the main gas supply path in the branch portion and supply branched process gases to the n reaction chambers; n first stop valves that are provided in the n sub gas supply paths between the branch portion and the n reaction chambers such that distances from the n first stop valves to the branch portion are less than distances from the n first stop valves to the reaction chambers and are capable of stopping the flow of the process gas; and n sub mass flow controllers that are provided in the n sub gas supply paths between the n first stop valves and the n reaction chambers and control the flow rate of the process gas through the n sub gas supply paths.

A vapor phase growth method according to another embodiment of the invention includes: loading substrates to each of n (n is an integer equal to or greater than 2) reaction chambers; introducing a process gas controlled to a predetermined flow rate to a main gas supply path; introducing branched process gases to n sub gas supply paths branched from the main gas supply path at a controlled flow rate; supplying the process gas from the n sub gas supply paths to the n reaction chambers to form films on the substrates; and when an abnormality occurs in one of the n reaction chambers, instantly stopping the introduction of the process gas to the sub gas supply paths connected to the reaction chamber in which the abnormality has occurred, calculating a total flow rate of the process gas supplied to the reaction chambers other than the reaction chamber from which the abnormality has been detected, and controlling the flow rate of the process gas introduced to the main gas supply path.

The vapor phase growth apparatus and the vapor phase growth method according to the embodiments have the above-mentioned structure. Therefore, when the process gas is distributed and supplied to a plurality of reaction chambers and an abnormality occurs in one reaction chamber during processing, it is possible to stop the supply of the process gas to the reaction chamber in which the abnormality has occurred, without greatly affecting processing in other reaction chambers. As a result, it is possible to achieve a vapor phase growth apparatus and a vapor phase growth method that, even when an abnormality occurs in processing in one reaction chamber, can continue to normally perform processing in other reaction chambers. The abnormality may be a state of a chamber in which desired deposition of a film cannot be performed. The abnormality may be temperature abnormality, pressure abnormality, and wafer rotation speed abnormality, for example.

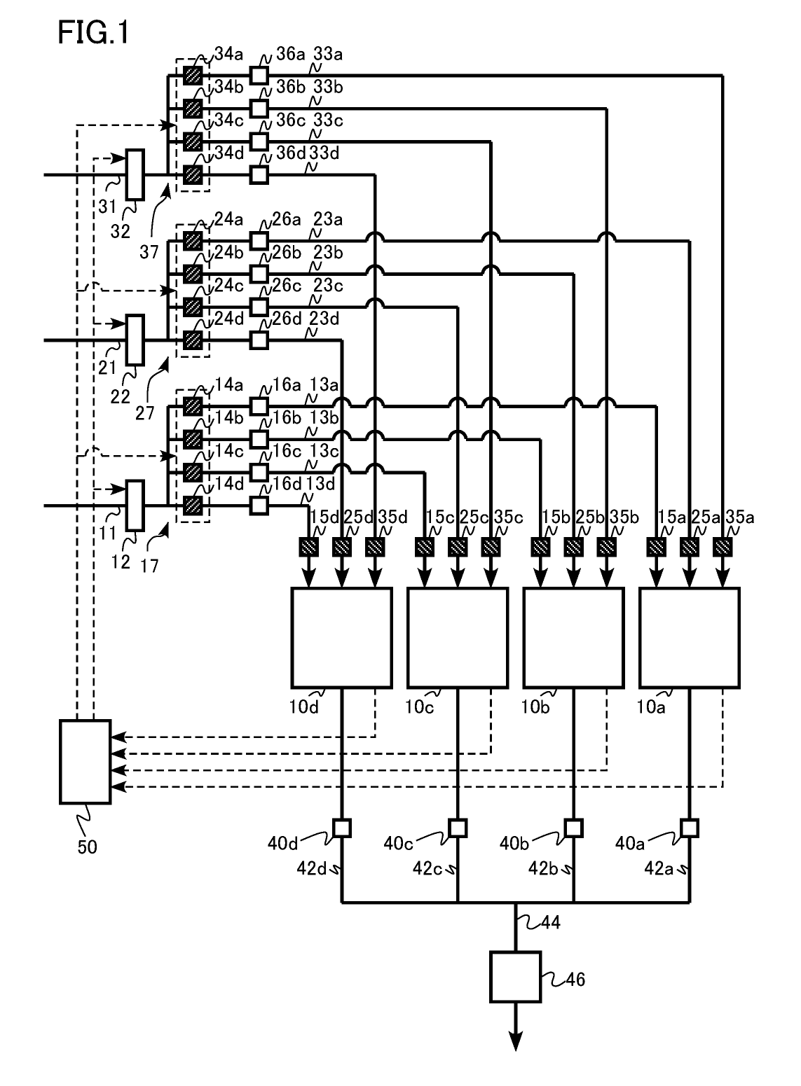

FIG. 1 is a diagram illustrating the structure of the vapor phase growth apparatus according to this embodiment. The vapor phase growth apparatus according to this embodiment is an epitaxial growth apparatus using a metal organic chemical vapor deposition (MOCVD) method. Hereinafter, an example in which gallium nitride (GaN) is epitaxially grown will be mainly described.

The vapor phase growth apparatus according to this embodiment includes four reaction chambers 10a, 10b, 10c, and 10d. Each of the four reaction chambers is, for example, a vertical single-wafer-type epitaxial growth apparatus. The number of reaction chambers is not limited to four and may be any value equal to or greater than 2. The number of reaction chambers can be represented by n (n is an integer equal to or greater than 2).

The vapor phase growth apparatus according to this embodiment includes three main gas supply paths, that is, a first main gas supply path 11, a second main gas supply path 21, and a third main gas supply path 31 that supply process gas to the four reaction chambers 10a to 10d.

For example, the first main gas supply path 11 supplies a first process gas including organic metal of a group-III element and carrier gas to the reaction chambers 10a to 10d. The first process gas is gas including a group-III element when a group III-V semiconductor film is formed on a wafer.

The group-III element is, for example, gallium (Ga), aluminum (Al), or indium (In). The organic metal is, for example, trimethylgallium (TMG) trimethyluminum (TMA), or trimethylindium (TMI).

The carrier gas is, for example, hydrogen gas. Only hydrogen gas may flow through the first main gas supply path 11.

A first main mass flow controller 12 is provided in the first main gas supply path 11. The first main mass flow controller 12 controls the flow rate of the first process gas through the first main gas supply path 11.

In addition, a branch portion 17 that branches the first main gas supply path 11 is provided. The first main gas supply path 11 is branched into four sub gas supply paths, that is, a first sub gas supply path 13a, a second sub gas supply path 13b, a third sub gas supply path 13c, and a fourth sub gas supply path 13d by the branch portion 17 at a position that is closer to the reaction chambers 10a to 10d than the first main mass flow controller 12. The first sub gas supply path 13a, the second sub gas supply path 13b, the third sub gas supply path 13c, and the fourth sub gas supply path 13d supply the branched first process gases to the four reaction chambers 10a, 10b, 10c, and 10d, respectively.

First stop valves 14a to 14d that can stop the flow of the first process gas are provided in the four sub gas supply paths 13a to 13d, respectively. When an abnormality occurs in any one of the four reaction chambers 10a, 10b, 10c, and 10d, the first stop valves 14a to 14d have a function of instantly stopping the flow of the process gas to the reaction chamber in which the abnormality has occurred.

The first stop valves 14a to 14d are provided between the branch portion 17 and the four reaction chambers 10a, 10b, 10c, and 10d, respectively. The first stop valves 14a to 14d are disposed such that the distances from the first stop valves 14a to 14d to the branch portion 17 are less than the distances from the first stop valves 14a to 14d to the reaction chambers 10a, 10b, 10c, and 10d.

It is preferable that the first stop valves 14a to 14d be provided so as to be adjacent to the branch portion 17. It is preferable that the distances between the branch portion 17 and the first stop valves 14a to 14d be equal to or greater than 20 cm and equal to or less than 30 cm.

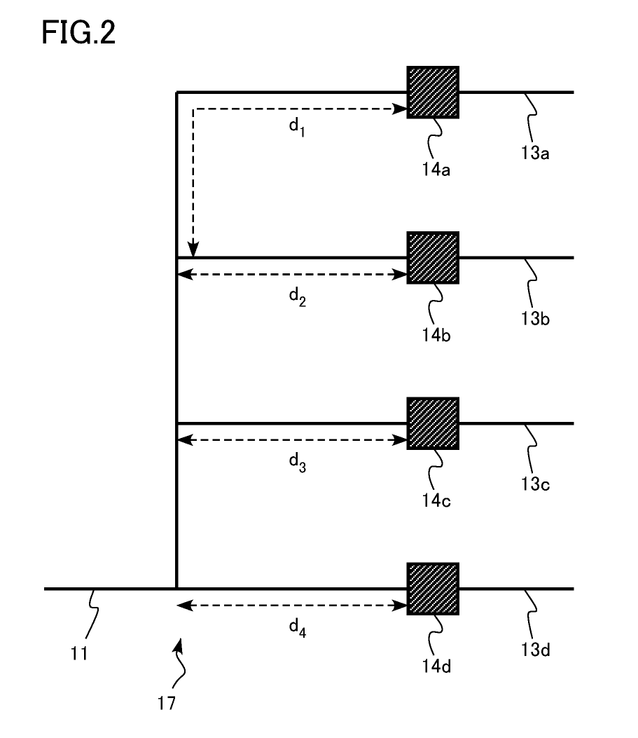

FIG. 2 is a diagram illustrating the branch portion and the first stop valves according to this embodiment.

Specifically, it is assumed that the distances between the branch portion 17 and the first stop valves 14a to 14d mean the distances from the point where the first main gas supply path 11 is finally branched into the sub gas supply paths 13a to 13d to the first stop valves 14a to 14d. That is, it is assumed that the distances between the branch portion 17 and the first stop valves 14a to 14d mean distances “d₁”, “d₂”; “d₃” and “d₄” illustrated in FIG. 2. It is preferable that the distances between the branch portion 17 and the first stop valves 14a to 14d be as short as possible.

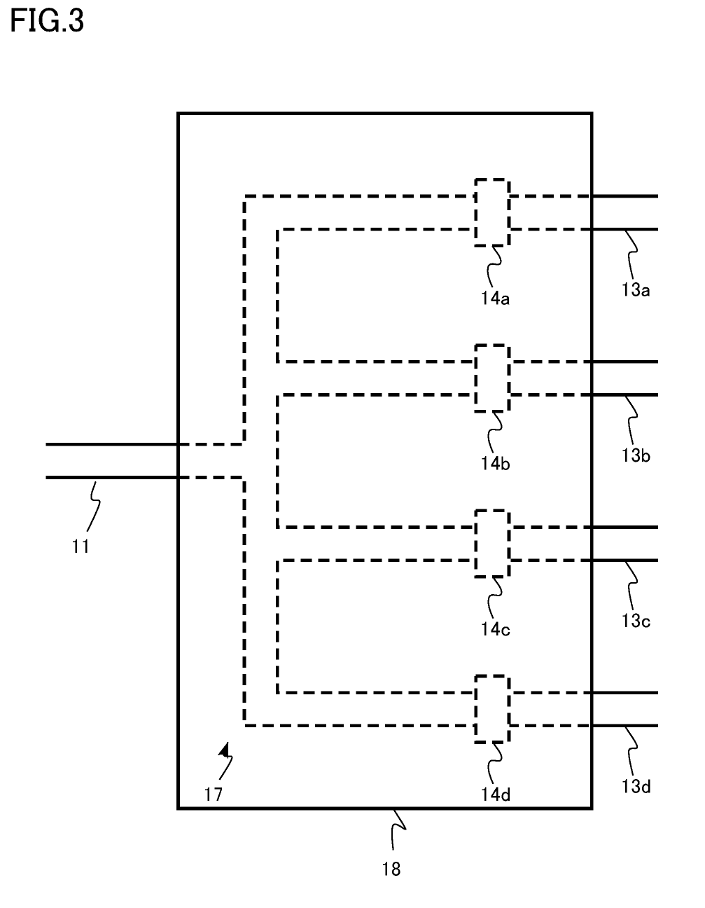

FIG. 3 is a diagram schematically illustrating the branch portion and the first stop valves according to this embodiment. For example, the branch portion 17 and the first stop valves 14a to 14d are integrally provided in a housing 18. The housing 18 includes the branch portion 17 and the first stop valves 14a to 14d. The first stop valves 14a to 14d are formed as, for example, one component. The housing 18 is made of, for example, metal.

The first main gas supply path 11 is connected to a portion of the outer surface of the housing 18 and the four sub gas supply paths 13a to 13d are connected to portions of the outer surface of the housing 18. Since the branch portion 17 and the first stop valves 14a to 14d are integrally provided in the housing 18, it is possible to reduce the distances between the branch portion 17 and the first stop valves 14a to 14d.

Four second stop valves 15a to 15d that can stop the flow of the first process gas are provided in the four sub gas supply paths 13a to 13d between the four first stop valves 14a to 14d and the four reaction chambers 10a, 10b, 10c, and 10d, respectively. For example, when the reaction chambers 10a to 10d are opened to the atmosphere for maintenance, the second stop valves 15a to 15d are closed to stop the upstream side from being opened to the atmosphere. The second stop valves 15a to 15d are provided at positions that are close to the reaction chambers 10a, 10b, 10c, and 10d.

Four sub mass flow controllers 16a to 16d that control the flow rate of the first process gas through the four sub gas supply paths 13a to 13d are further provided in the four sub gas supply paths 13a to 13d between the four first stop valves 14a to 14d and the four second stop valves 15a to 15d, respectively.

It is preferable to provide the second stop valves 15a to 15d between the sub mass flow controllers 16a to 16d and the reaction chambers 10a to 10d in order to prevent the four sub mass flow controllers 16a to 16d from being exposed to the atmosphere when the reaction chambers 10a to 10d are opened to the atmosphere.

For example, the second main gas supply path 21 supplies a second process gas including ammonia (NH₃) to the reaction chambers 10a to 10d. The second process gas is the source gas of a group-V element and nitrogen (N) when a group III-V semiconductor film is formed on a wafer.

Only hydrogen gas may flow through the second main gas supply path 21.

A second main mass flow controller 22 is provided in the second main gas supply path 21. The second main mass flow controller 22 controls the flow rate of the second process gas through the second main gas supply path 21.

In addition, a branch portion 27, sub gas supply paths 23a to 23d, first stop valves 24a to 24d, second. stop valves 25a to 25d, and sub mass flow controllers 26a to 26d which are connected to the second main gas supply path 21 are provided. Since the structure and function of each of the components are the same as those of the branch portion 17, the sub gas supply paths 13a to 13d, the first stop valves 14a to 14d, the second stop valves 15a to 15d, and the sub mass flow controllers 16a to 16d connected to the first main gas supply path 11, the description thereof will not be repeated.

For example, the third main gas supply path 31 supplies hydrogen gas as a third process gas to the reaction chambers 10a to 10d. The third process gas is separation gas for separating the first process gas from the second process gas.

Only hydrogen gas may flow through the third main gas supply path 31.

A third main mass flow controller 32 is provided in the third main gas supply path 31. The third main mass flow controller 32 controls the flow rate of the third process gas through the third main gas supply path 31.

In addition, a branch portion 37, sub gas supply paths 33a to 33d, first stop valves 34a to 34d, second stop valves 35a to 35d, and sub mass flow controllers 36a to 36d which are connected to the third main gas supply path 31 are provided. Since the structure and function of each of the components are the same as those of the branch portion 17, the sub gas supply paths 13a to 13d, the first stop valves 14a to 14d, the second stop valves 15a to 15d, and the sub mass flow controllers 16a to 16d connected to the first main gas supply path 11, the description thereof will not be repeated.

The vapor phase growth apparatus according to this embodiment includes four sub gas exhaust paths 42a, 42b, 42c, and 42d that discharge gas from the four reaction chambers 10a, 10b, 10c, and 10d, respectively. In addition, the vapor phase growth apparatus includes a main gas exhaust path 44 to which the four sub gas exhaust paths 42a, 42b, 42c, and 42d are connected. A vacuum pump 46 that draws gas is provided in the main gas exhaust path 44.

Pressure adjustment units 40a, 40b, 40c, and 40d are provided in the four sub gas exhaust paths 42a, 42b, 42c, and 42d, respectively. The pressure adjustment units 40a, 40b, 40c, and 40d control the internal pressure of the reaction chambers 10a to 10d such that it becomes a desired value, respectively. The pressure adjustment units 40a to 40d are, for example, throttle valves. Instead of the pressure adjustment units 40a, 40b, 40c, and 40d, one pressure adjustment unit may be provided in the main gas exhaust path 44.

The vapor phase growth apparatus according to this embodiment includes a flow rate controller 50 that controls the main mass flow controllers 12, 22, and 32 and the first stop valves 14a to 14d, 24a to 24d, and 34a to 34d. The flow rate controller 50 determines whether to stop the flow of the process gas on the basis of the detection of an abnormality in one of the four reaction chambers 10a, 10b, 10c, and 10d. When determining that the flow of the process gas needs to be stopped, the flow rate controller 50 has a function of closing the first stop valve that can stop the flow of the process gas to the reaction chamber from which the abnormality has been detected, calculating the total flow rate of the process gas supplied to the reaction chambers other than the reaction chamber from which the abnormality has been detected, and controlling the main mass flow controllers on the basis of the calculated total flow rate.

A vapor phase growth method according to this embodiment uses the epitaxial growth apparatus illustrated in FIG. 1. Next, the vapor phase growth method according to this embodiment will be described using an example in which GaN is epitaxially grown.

In the vapor phase growth method according to this embodiment, a reaction chamber control unit (not illustrated) controls the vapor phase growth conditions of the four reaction chambers 10a to 10d at the same time such that the vapor phase growth conditions are the same.

First, a semiconductor wafer which is an example of the substrate is loaded to each of the four reaction chambers 10a to 10d.

For example, when a GaN film is formed on the semiconductor wafer, TMG (first process gas) having hydrogen gas as the carrier gas is supplied from the first main gas supply path 11. In addition, for example, ammonia (second process gas) is supplied from the second main gas supply path 21. For example, hydrogen gas (third process gas) is supplied as the separation gas from the third main gas supply path 31.

The first process gas flows to the first main gas supply path 11, the flow rate of the first process gas has been controlled by the first main mass flow controller 12. Then, the first process gas is branched and flows to the four sub gas supply paths 13a, 13b, 13c, and 13d branched from the first main gas supply path 11.

The sub mass flow controllers 16a, 16b, 16c, and 16d control the flow rate of the first process gas which is branched and flows to the four sub gas supply paths 13a, 13b, 13c, and 13d, respectively. For example, the flow rate controlled by the sub mass flow controllers 16a, 16b, 16c, and 16d is designated such that the flow rate is one fourth (¼) of the total flow rate of the first process gas designated by the first main mass flow controller 12.

The second process gas, of which the flow rate has been controlled by the second main mass flow controller 22, flows to the second main gas supply path 21. Then, the second process gas is branched and flows to the four sub gas supply paths 23a, 23b, 23c, and 23d branched from the second main gas supply path 21.

The sub mass flow controllers 26a, 26b, 26c, and 26d control the flow rate of the second process gas which is branched and flows to the four sub gas supply paths 23a, 23b, 23c, and 23d, respectively. For example, the flow rate controlled by the sub mass flow controllers 26a, 26b, 26c, and 26d is designated such that the flow rate is one fourth (¼) of the total flow rate of the second process gas designated by the second main mass flow controller 22.

The third process gas, of which the flow rate has been controlled by the third main mass flow controller 32, flows to the third main gas supply path 31. Then, the third process gas is branched and flows to the four sub gas supply paths 33a, 33b, 33c, and 33d branched from the third main gas supply path 31.

The sub mass flow controllers 36a, 36b, 36c, and 36d control the flow rate of the third process gas which is branched and flows to the four sub gas supply paths 33a, 33b, 33c, and 33d, respectively. For example, the flow rate controlled by the sub mass flow controllers 36a, 36b, 36c, and 36d is designated such that the flow rate is one fourth (¼) of the total flow rate of the third process gas designated by the third main mass flow controller 32.

The pressure adjustment units 40a to 40d control the internal pressures of the reaction chambers 10a to 10d such that the internal pressures are equal to each other.

As such, the first, second, and third process gases are supplied to each of the reaction chambers 10a to 10d and a GaN film is formed on the semiconductor wafer.

A reaction chamber control unit (not illustrated) controls the vapor phase growth conditions of the four reaction chambers 10a, 10b, 10c, and 10d such that the vapor phase growth conditions are the same, that is, processing recipes are the same. For example, the reaction chamber control unit controls the sub mass flow controllers 16a, 26a, and 36a using the same processing recipe. In addition, the reaction chamber control unit controls the sub mass flow controllers 16b, 26b, and 36b using the same processing recipe. The reaction chamber control unit controls the sub mass flow controllers 16c, 26c, and 36c using the same processing recipe. The reaction chamber control unit controls the sub mass flow controllers 16d, 26d, and 36d using the same processing recipe. The reaction chamber control unit controls the pressure adjustment units 40a, 40b, 40c, and 40d using the same processing recipe. The reaction chamber control unit controls, for example, the temperature of the reaction chambers 10a, 10b, 10c, and 10d or the number of rotations of the substrate using the same processing recipe.

When a failure occurs in processing in any one of the four reaction chambers 10a, 10b, 10c, and 10d, the reaction chamber control unit closes some of the first stop valves 14a to 14d, 24a, to 24d, and 34a to 34d to instantly stop the introduction of the process gas to the sub gas supply paths 13a to 13d, 23a to 23d, and 33a to 33d connected to the reaction chamber in which the abnormality has occurred. In this way, the reaction chamber control unit instantly stops the supply of the process gas to the reaction chamber in which the abnormality has occurred. In contrast, processing is continuously performed in the remaining three normal reaction chambers.

For example, when an abnormality occurs in processing in the reaction chamber 10a, the reaction chamber control unit instantly closes the first stop valves 14a, 24a, and 34a to instantly stop the introduction of the process gas to the sub gas supply paths 13a, 23a, and 33a. In this way, the reaction chamber control unit stops the supply of the first, second, and third process gases to the reaction chamber 10a. In contrast, processing is continuously performed in the reaction chambers 10b, 10c, and 10d.

For example, the first, second, and third main mass flow controllers 12, 22, and 32 change the total flow rate of the first, second, and third process gases to be supplied to three-fourths of the total flow rate before an abnormality occurs such that the process gases are supplied to the reaction chambers 10b, 10c, and 10d that operate normally at a desired flow rate.

For example, the flow rate controller 50 determines whether to stop the supply of the process gas on the basis of the detection of an abnormality in any one of the four reaction chambers 10a, 10b, 10c, and 10d. When determining that the supply of the process gas needs to be stopped, the flow rate controller 50 closes the first stop valves that can stop the flow of the process gas to the reaction chamber from which the abnormality has been detected.

Then, the flow rate controller 50 calculates the total flow rate of the process gas to be supplied to the reaction chambers other than the reaction chamber from which the abnormality has been detected, controls the main mass flow controllers 12, 22, and 32 on the basis of the calculated total flow rate, and controls the flow rate of the process gas to be introduced to the main gas supply paths 11, 21, and 31.

Next, the function and effect of this embodiment will be described.

When an abnormality occurs in processing in one of the four reaction chambers 10a, 10b, 10c, and 10d, it is preferable to stop the supply of the process gas to the reaction chamber in which the abnormality has occurred and to stop processing. For example, when the process gas is continuously supplied to the reaction chamber in which the abnormality has occurred, similarly to the remaining three reaction chambers, the process gas that does riot contribute to deposition is wasted. Alternatively, for example, unexpected gas reaction is likely to occur and the amount of dust in the reaction chamber is likely to increase.

It is preferable that processing be continuously performed in the remaining three normal reaction chambers in terms of productivity. However, for example, when the first stop valves 14a to 14d, 24a to 24d, and 34a to 34d are not provided so as to be adjacent to the branch portions 17, 27, and 37 in the epitaxial growth apparatus, some of the second stop valves 15a to 15d, 25a to 25d, and 35a to 35d which are provided close to the reaction chambers are closed to stop the supply of the process gas to the reaction chamber in which the abnormality has occurred.

For example, when an abnormality occurs in processing in the reaction chamber 10a and the first stop valves 14a, 24a, and 34a are not provided, the second stop valves 15a, 25a, and 35a are instantly closed to stop the supply of the first, second, and third process gases to the reaction chamber 10a. In contrast, processing is continuously performed in the reaction chambers 10b, 10c, and 10d.

In this case, a space from the branch portion 17 to the second stop valve 15a, a space from the branch portion 27 to the second stop valve 25a, and a space from the branch portion 37 to the second stop valve 35a are dead spaces in which the process as stays. When the amount of process gas staying in the dead space is large, process gas with an unexpected composition or the unexpected amount of process gas is supplied to the reaction chambers 10b, 110c, and 10d that operate normally. As a result, there is a concern that an abnormality will occur in processing.

For example, when a process of changing the type of process gas is performed after processing in the reaction chamber 10a is stopped, there is a concern that the process gas staying in the dead space will be mixed with the changed process gas, process gas with an unexpected composition will be supplied to the reaction chambers 10b, 10c, and 10d, and an abnormality will occur in deposition in the reaction chambers 10b 10c, and 10d.

The epitaxial vapor phase growth apparatus according to this embodiment includes the first stop valves 14a, 24a, and 34a provided such that the distances from the first stop valves 14a, 24a, and 34a to the branch portions 17, 27, and 37 are less than the distances from the first stop valves 14a, 24a, and 34a to the reaction chamber 10a. Therefore, the dead space of a gas supply tube is smaller than that in a case in which the first stop valves 14a, 24a, and 34a are not provided and it is possible to reduce the amount of process gas staying in the dead space. As a result, even when an abnormality occurs in processing in the reaction chamber 10a, processing can continue to be normally performed in other reaction chambers 10b, 10c, and 10d.

In addition, it is possible to change the total flow rate or the process gas supplied to the reaction chambers other than the reaction chamber, from which an abnormality has been detected, to a predetermined value in a short time in synchronization with the stopping of the supply of the process gas to the reaction chamber from which the abnormality has been detected and it is easy to continue to normally perform processing in other reaction chambers 10b, 10c, and 10d.

It is preferable that the first stop valves 14a, 24a, and 34a be adjacent to the branch portions 17, 27, and 37 in order to reduce the amount of process gas staying in the dead space. It is preferable that the distances between the first stop valves 14a, 24a, and 34a and the branch portions 17, 27, and 37 be equal to or greater than 20 cm and equal to or less than 30 cm. When the distance is less than the above-mentioned range, it is difficult to manufacture the stop valves. When the distance is greater than the above-mentioned range, there is a concern that the distance will affect the amount of process gas staving in the dead space.

According to this embodiment, the second stop valves 15a, 25a, and 35a are provided so as to be adjacent to the reaction chamber 10a, separately from the first stop valves 14a, 24a, and 34a. Therefore, it is possible to prevent the sub gas supply paths 13a, 23a, and 33a or the sub mass flow controllers 16a, 26a, and 36a from being opened to the atmosphere during maintenance.

When an abnormality is detected during deposition, it is preferable that the supply of the process gas be maintained until the deposition conditions are changed and then the introduction of the process gas to the sub gas supply paths connected to the reaction chamber, in which the abnormality has occurred, be instantly stopped, in order to prevent the influence of the abnormality on deposition in the reaction chambers that operate normally.

In this embodiment, an example of the maintenance of the reaction chamber 10a when an abnormality occurs in the reaction chamber 10a has been described above. However, the epitaxial vapor phase growth apparatus according to this embodiment has the same function and effect as described above for other reaction chambers 10b, 10c, and 10d.

As described above, according to the vapor phase growth apparatus according to this embodiment, it is possible to provide a vapor phase growth apparatus and a vapor phase growth method that, when an abnormality occurs in processing in one reaction chamber, can continue to normally perform processing in other reaction chambers.

The embodiments of the invention have been described above with reference to examples. The above-described embodiments are just an example and do not limit the invention. The components of each embodiment may be appropriately combined with each other.

For example, in the embodiment, an example in which a gallium nitride (GaN) single-crystal film is formed has been described. However, the invention may be applied to form other group III-V nitride-based semiconductor single-crystal films, such as an aluminum nitride (AlN) film, an aluminum gallium nitride (AlGaN) film, or an indium gallium nitride (InGaN) film. In addition, the invention may be applied to a group III-V semiconductor such as GaAs.

In the above-described embodiment, one kind of TMG is used as the organic metal. However, two or more kinds of organic metal may be used as the source of a group-III element. In addition, the organic metal may be elements other than the group-III element.

In the above-described embodiment, hydrogen gas (H₂) is used as the carrier gas. However, the invention is not limited thereto. For example, nitrogen gas (N₂), argon gas (Ar), helium gas (He), or a combination thereof may be applied as the carrier gas.

In addition, the process gas may be, for example, mixed gas including a group-III element and a group-V element.

In the above-described embodiment, the epitaxial apparatus is the vertical single wafer type in which a deposition process is performed for each wafer in n reaction chambers. However, the application of the n reaction chambers is not limited to the single-wafer-type epitaxial apparatus. For example, the invention may be applied a horizontal epitaxial apparatus or a planetary CVD apparatus that simultaneously forms films on a plurality of wafers which rotate on their own axes while revolving around the apparatus.

In the above-described embodiment, for example, portions which are not necessary to describe the invention, such as the structure of the apparatus or a manufacturing method, are not described. However, the necessary structure of the apparatus or a necessary manufacturing method can be appropriately selected and used. In addition, all of the vapor phase growth apparatuses and the vapor phase growth methods which include the components according to the invention and whose design can be appropriately changed by those skilled in the art are included in the scope of the invention. The scope of the invention is defined by the scope of the claims and the scope of equivalents thereof.

What is claimed is:

1. A vapor phase growth apparatus comprising:
n (n is an integer equal to or greater than 2) reaction chambers;
a main gas supply path supplying a process gas to the n reaction chambers;
a main mass flow controller provided in the main gas supply path, the main mass flow controller controlling a flow rate of the process gas through the main gas supply path;
a branch portion branching the main gas supply path;
n sub gas supply paths branched from the main gas supply path at the branch portion, the n sub gas supply paths supplying branched process gases to the n reaction chambers;
n first stop valves provided in the n sub gas supply paths between the branch portion and the n reaction chambers, distances from the n first stop valves to the branch portion are less than distances from the n first stop valves to the n reaction chambers, the n first stop valves being capable of stopping the flow of the process gas to the n reaction chambers; and
n sub mass flow controllers provided in the n sub gas supply paths between the n first stop valves and the n reaction chambers, the n sub mass flow controllers controlling a flow rate of the process gas through the n sub gas supply paths.

2. The vapor phase growth apparatus according to claim 1, further comprising:
a flow rate controller determining whether to stop a flow of the process gas to one of the n reaction chambers in which an abnormality occurred,
when the flow of the process gas to the one of the n reaction chambers needs to be stopped, the flow rate controller instructing to close one of the n first stop valves capable of stopping the flow of the process gas to the one of the n reaction chambers, the flow rate controller calculating a total flow rate of the process gas supplied to the n reaction chambers other than the one of the n react on chambers, the flow rate controller controlling the main mass flow controllers on the basis of calculated total flow rate of the process gas supplied to the n reaction chambers other than the one of the n reaction chambers.

3. The vapor phase growth apparatus according to claim 1, further comprising:
n second stop valves provided in the n sub gas supply paths between the n first stop valves and the n reaction chambers, the n second stop valves being capable of stopping the flow of the process gas to the n reaction chambers.

4. The vapor phase growth apparatus according to claim 1,
wherein the branch portion and the n first stop valves are provided so as to be adjacent to each other.

5. The vapor phase growth apparatus according to claim 1,
wherein the distances between the branch portion and the n first stop valves are equal to or greater than 20 cm and equal to or less than 30 cm.

6. The vapor phase growth apparatus according to claim 1, further comprising:
a housing including the branch portion and the n first stop valves.

7. The vapor phase growth apparatus according to claim 1,
wherein the housing is made of metal.

8. The vapor phase growth apparatus according to claim 1,
wherein the branch portion and the n first stop valves are integrated into one component.

9. A vapor phase growth method comprising:
loading substrates to each of n (n is an integer equal to or greater than 2) reaction chambers;
introducing a process gas controlled to a predetermined flow rate to a main gas supply path;
introducing branched process gases to n sub gas supply paths branched from the main gas supply path at a controlled flow rate;
supplying the process gas from the n sub gas supply paths to the n reaction chambers to form films on the substrates; and
when an abnormality occurs in one of the n reaction chambers, stopping the introduction of one of the branched process gases to one of the n sub gas supply paths connected to the one of the n reaction chambers, calculating a total flow rate of the process gas supplied to n reaction chambers other than the one of the n reaction chambers, and controlling the flow rate of the process gas introduced to the main gas supply path.

10. The vapor phase growth method according to claim 9,
wherein, when the abnormality is occurred during deposition, supply of the one of the branched process gases is maintained until deposition conditions are changed and then the introduction of the one of the branched process gases to the one of the n sub gas supply paths connected to the one of the n reaction chambers is instantly stopped.
